(19) United States
(12) Patent Application Publication
(10) Pub. No.: US 2026/0190369 A1
(43) Pub. Date: Jul. 2, 2026

(54) SEMICONDUCTOR STRUCTURE AND FABRICATION METHOD THEREOF

(71) Applicant: Semiconductor Manufacturing International (Shanghai) Corporation, Shanghai (CN)

(72) Inventors: Jaewoo KIM, Shanghai (CN); Weinan JIN, Shanghai (CN)

(21) Appl. No.: 19/434,441

(22) Filed: Dec. 29, 2025

(30) Foreign Application Priority Data
Dec. 30, 2024 (CN) 202411980778.3

(51) Int. Cl. H10D 30/01; C30B 1/02; C30B 29/06; C30B 29/68; H10D 30/00; H10P 14/60

(52) U.S. Cl. CPC H10D 30/0191; C30B 1/02; C30B 29/06; C30B 29/68; H10D 30/502; H10P 14/6306

(57) ABSTRACT

A semiconductor structure and a fabrication method of the semiconductor structure are provided in the present disclosure. The semiconductor structure includes a substrate; an isolation layer on the substrate; a growth layer on the isolation layer and configured to grow a channel material; a channel layer structure suspended above the growth layer, where the channel layer structure includes one or more channel layers spaced from each other along a vertical direction; a gate structure over the substrate and crossing the channel layer structure, where the gate structure is around the one or more channel layers along an extension direction of the gate structure; and a source doped layer and a drain doped layer, over the substrate at two opposite sides of the gate structure. The source doped layer and the drain doped layer are in contact with ends of the channel layer structure.

### CROSS REFERENCE TO RELATED APPLICATION

This application claims the priority of Chinese Patent Application No. 202411980778.3, filed on Dec. 30, 2024, the content of which is incorporated herein by reference in its entirety.

### TECHNICAL FIELD

The present disclosure generally relates to the field of semiconductor manufacturing and, more particularly, relates to a semiconductor structure and a fabrication method thereof.

### BACKGROUND

Gate-all-around (GAA) transistors can carry higher currents while maintaining relatively small sizes. GAA transistors have evolved from fin field-effect transistors (FinFETs). Compared to FinFETs, GAA transistors may lower the supply voltages and increase current drive capability, thereby further improving performance.

Using GAA transistors in large-scale or even ultra-large-scale integrated circuits may lead to significant bottom parasitic channel leakage. To address such issue, a bottom dielectric isolation (BDI) layer may be placed below the regions including the source, the drain, and the gate of the GAA transistor.

### SUMMARY

One aspect of the present disclosure provides a semiconductor structure. The semiconductor structure includes a substrate; an isolation layer on the substrate; a growth layer on the isolation layer and configured to grow a channel material; a channel layer structure suspended above the growth layer, where the channel layer structure includes one or more channel layers spaced from each other along a vertical direction; a gate structure over the substrate and crossing the channel layer structure, where the gate structure is around the one or more channel layers along an extension direction of the gate structure; and a source doped layer and a drain doped layer over the substrate at two opposite sides of the gate structure. Along an extension direction of the channel layer structure, the source doped layer and the drain doped layer are in contact with ends of the channel layer structure.

Optionally, the isolation layer covers the substrate; and the source doped layer and the drain doped layer are on the isolation layer which is on the substrate.

Optionally, a sidewall of the growth layer is coplanar with the end of the channel layer structure; and along the extension direction of the channel layer structure, the source doped layer and the drain doped layer are also in contact with sidewalls of the growth layer.

Optionally, the substrate material is made of a material including silicon.

Optionally, the isolation layer is made of a material including silicon oxide, silicon nitride, or a combination thereof.

Optionally, the growth layer is made of a material including silicon which includes single crystalline silicon or epitaxial-like crystalline silicon.

Optionally, the channel layer is made of a material including silicon, germanium, silicon germanium, a Group III-V semiconductor material, or a combination thereof.

Another aspect of the present disclosure provides a fabrication method of a semiconductor structure. The method includes providing a substrate; forming an isolation layer on the substrate; forming a growth layer on the isolation layer, where the growth layer is configured to grow a channel material; growing a stacked-layer structure on the growth layer, where the stacked-layer structure includes one or more channel-stack layers which are stacked with each other, and a channel-stack layer includes a sacrificial layer and a channel layer on the sacrificial layer; forming a dummy gate structure crossing the stacked-layer structure, where the dummy gate structure covers a sidewall and a top of the stacked-layer structure; forming a source doped layer and a drain doped layer over the substrate at two opposite sides of the dummy gate structure, where the source doped layer and the drain doped layer are in contact with ends of the stacked-layer structure along an extension direction of the stacked-layer structure; removing the dummy gate structure and sacrificial layers, and retaining one or more channel layers, spaced from each other along a vertical direction, as a channel layer structure suspended above the growth layer; and forming a gate structure, crossing the channel layer structure, over the substrate, where the gate structure is around the one or more channel layers along an extension direction of the gate structure.

Optionally, forming the isolation layer on the substrate includes forming the isolation layer, which covers the substrate, on the substrate.

Optionally, the isolation layer which covers the substrate is formed using a deposition process.

Optionally, forming the isolation layer on the substrate includes converting a top portion of the substrate into the isolation layer and retaining a remaining portion of the substrate.

Optionally, an oxidation processing is performed on the top portion of the substrate to convert the top portion of the substrate into the isolation layer.

Optionally, performing the oxidation processing on the top portion of the substrate to convert the top portion of the substrate into the isolation layer includes: performing the oxidation processing on the top portion of the substrate using an in-situ water vapor oxidation process; or performing an oxygen ion implantation processing on the top portion of the substrate, and after performing the oxygen ion implantation processing, performing an annealing processing on the top portion of the substrate.

Optionally, forming the growth layer on the isolation layer includes forming an initial growth layer covering the isolation layer; and performing lattice reorganization on the initial growth layer to form the growth layer.

Optionally, for forming the initial growth layer covering the isolation layer, the initial growth layer is made of a material including polycrystalline silicon; and for performing the lattice reorganization on the initial growth layer to form the growth layer, the growth layer is made of a material including single crystalline silicon and/or epitaxial-like crystalline silicon.

Optionally, the initial growth layer covering the isolation layer is formed using a deposition process.

Optionally, a laser processing is configured to perform the lattice reorganization on the initial growth layer to form the growth layer.

Optionally, the stacked-layer structure is grown on the growth layer using an epitaxial growth process.

Optionally, forming the source doped layer and the drain doped layer over the substrate at two opposite sides of the dummy gate structure includes forming the source doped layer and the drain doped layer on the isolation layer which is on the substrate at two opposite sides of the dummy gate structure.

Optionally, for forming the source doped layer and the drain doped layer over the substrate at two opposite sides of the dummy gate structure, the source doped layer and the drain doped layer are further in contact with sidewalls of the growth layer along the extension direction of the stacked-layer structure.

Compared with the existing technology, the technical solutions provided by the present disclosure may achieve at least following beneficial effects.

In the semiconductor structure provided by embodiments of the present disclosure, the isolation layer may be on the substrate; the growth layer may be on the isolation layer, where the growth layer may be configured to grow the channel material; and the channel layer structure may be suspended above the growth layer, where the channel layer structure may include one or more channel layers spaced apart along the vertical direction. In embodiments of the present disclosure, the growth layer for growing the channel material may be formed on the isolation layer. Therefore, during the fabrication process, the isolation layer may be first formed; and after the growth layer is formed on the isolation layer, the channel layer structure may be grown on the growth layer, which may realize the process operation of pre-forming the isolation layer before forming the channel layer structure. Compared to the solution that the pre-buried layer is first formed at the location for the isolation layer to be formed and the pre-buried layer is removed to form the isolation layer after the channel layer structure is formed, in the solution provided by the present disclosure, the operations of removing the pre-buried layer and filling the location of the pre-buried layer to form the isolation layer may be omitted, which may simplify process flow, improve process efficiency, avoid damage to the channel layer structure during removal of the pre-buried layer, and also avoid the difficulty in desirably forming the isolation layer due to relatively high process difficulty at the position for filling the pre-buried layer, thereby being beneficial for forming the isolation layer with relatively high-quality film layer, reducing restriction on the film-layer thickness of the isolation layer, and ensuring the isolation performance of the isolation layer. In such way, the channel layer structure may be effectively isolated from the substrate by the isolation layer, thereby being beneficial for reducing the probability of leakage current between the channel layer structure and the substrate and further improving the performance of the semiconductor structure.

In the fabrication method provided by embodiments of the present disclosure, the isolation layer may be formed on the substrate; the growth layer may be formed on the isolation layer, where the growth layer may be configured to grow the channel material; and the stacked-layer structure may be grown on the growth layer, where the stacked-layer structure may include one or more channel-stack layers which are stacked with each other, and the channel-stack layer may include the sacrificial layer and the channel layer on the sacrificial layer. In embodiments of the present disclosure, the growth layer for growing the channel material may be formed on the isolation layer; and the stacked-layer structure may be grown on the growth layer, which may realize the process operation of pre-forming the isolation layer before forming the stacked-layer structure. Compared to the solution that the pre-buried layer is first formed at the location for the isolation layer to be formed and the pre-buried layer is removed to form the isolation layer after the stacked-layer structure is formed, in the solution provided by the present disclosure, the operations of removing the pre-buried layer and filling the location of the pre-buried layer to form the isolation layer may be omitted, which may simplify process flow, improve process efficiency, avoid damage to the stacked-layer structure during removal of the pre-buried layer, and also avoid the difficulty in desirably forming the isolation layer due to relatively high process difficulty at the position for filling the pre-buried layer, thereby being beneficial for forming the isolation layer with relatively high-quality film layer, reducing restriction on the film-layer thickness of the isolation layer, and ensuring the isolation performance of the isolation layer. In such way, the channel layer structure may be effectively isolated from the substrate by the isolation layer, thereby being beneficial for reducing the probability of leakage current between the channel layer structure and the substrate and further improving the performance of the semiconductor structure.

### BRIEF DESCRIPTION OF THE DRAWINGS

The following drawings are merely examples for illustrative purposes according to various disclosed embodiments and are not intended to limit the scope of the present disclosure.

FIGS. 1-3 illustrate structural schematics corresponding to certain stages of an exemplary fabrication method of a semiconductor structure.

FIG. 4 illustrates a structural schematic of an exemplary semiconductor structure according to various disclosed embodiments of the present disclosure.

FIGS. 5-12 illustrate structural schematics corresponding to certain stages of an exemplary fabrication method of a semiconductor structure according to various disclosed embodiments of the present disclosure.

FIG. 13 illustrates a flowchart of an exemplary fabrication method of a semiconductor structure according to various disclosed embodiments of the present disclosure.

### DETAILED DESCRIPTION

References are made in detail to exemplary embodiments of the disclosure, which are illustrated in accompanying drawings. Wherever possible, same reference numbers are used throughout accompanying drawings to refer to same or like parts.

A semiconductor structure and a fabrication method of the semiconductor structure are provided in the present disclosure. The semiconductor structure includes a substrate; an isolation layer on the substrate; a growth layer on the isolation layer and configured to grow a channel material; a channel layer structure suspended above the growth layer, where the channel layer structure includes one or more channel layers spaced from each other along a vertical direction; a gate structure over the substrate and crossing the channel layer structure, where the gate structure is around the one or more channel layers along an extension direction of the gate structure; and a source doped layer and a drain doped layer over the substrate at two opposite sides of the gate structure. Along an extension direction of the channel layer structure, the source doped layer and the drain doped layer are in contact with ends of the channel layer structure.

The performance of current semiconductor structures needs to be improved. The present disclosure provides a fabrication method of a semiconductor structure to overcome above-mentioned problems.

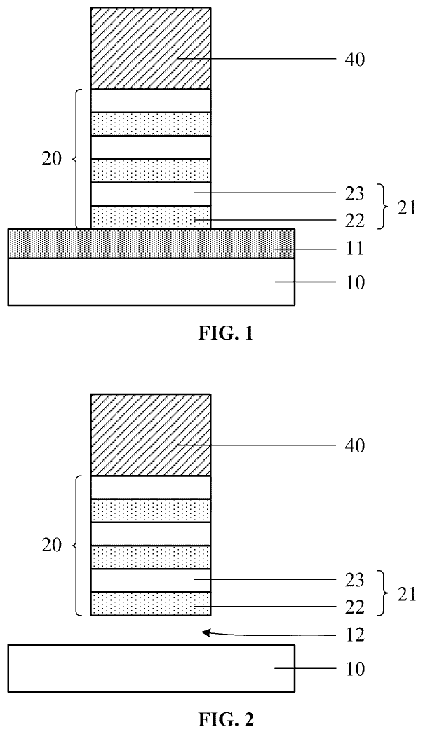

FIGS. 1-3 illustrate structural schematics corresponding to certain stages of an exemplary fabrication method of a semiconductor structure.

Referring to FIG. 1, a substrate 10 may be provided; a pre-buried layer 11 may be formed on the substrate 10; a stacked-layer structure 20 may be formed on the pre-buried layer 11, where the stacked-layer structure 20 may include one or more channel-stack layers 21 which are stacked with each other, and the channel-stack layer may include a sacrificial layer 22 and a channel layer 23 on the sacrificial layer 22; and a dummy gate structure 40 crossing the stacked-layer structure 20 may be formed, where the dummy gate structure 40 may cover a portion of the sidewall and a portion of the top of the stacked-layer structure 20.

Referring to FIG. 2, the pre-buried layer 11 may be removed to form a groove 12.

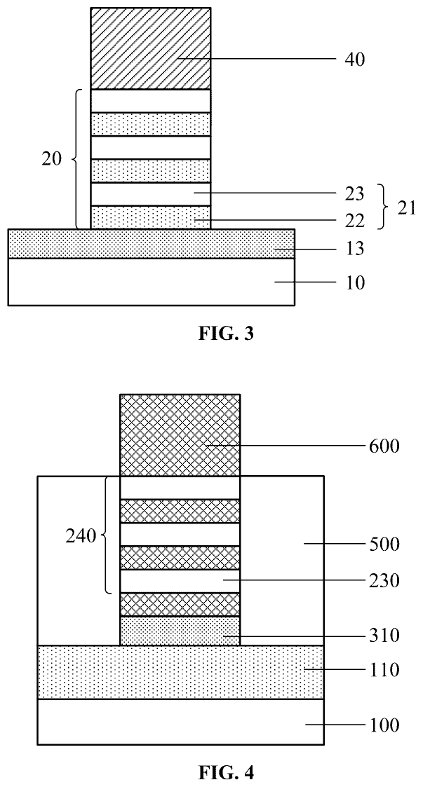

Referring to FIG. 3, an isolation layer 13 may be formed in the groove 12.

The pre-buried layer 11 may be first formed; and the pre-buried layer 11 may be removed to form the groove 12 for forming the isolation layer 13. The removal of the pre-buried layer 11 may easily damage the stacked-layer structure 20. The process of forming the isolation layer 13 in the groove 12 may be difficult, which may easily lead to poor quality of the isolation layer 13. Furthermore, the thickness of the isolation layer 13 may be limited, which may result in poor isolation performance of the isolation layer 13 and affect the isolation between the channel layer 23 and the substrate 10, thereby affecting the performance of the semiconductor structure.

To solve above-mentioned technical problems, various embodiments of the present disclosure provide a fabrication method of a semiconductor structure. The method may include providing a substrate; forming an isolation layer on the substrate; forming a growth layer on the isolation layer, where the growth layer is configured to grow a channel material; growing a stacked-layer structure on the growth layer, where the stacked-layer structure includes one or more channel-stack layers which are stacked with each other, and a channel-stack layer includes a sacrificial layer and a channel layer on the sacrificial layer; forming a dummy gate structure crossing the stacked-layer structure, where the dummy gate structure covers a sidewall and a top of the stacked-layer structure; forming a source doped layer and a drain doped layer over the substrate at two opposite sides of the dummy gate structure, where the source doped layer and the drain doped layer are in contact with ends of the stacked-layer structure along an extension direction of the stacked-layer structure; removing the dummy gate structure and sacrificial layers, and retaining one or more channel layers, spaced from each other along a vertical direction, as a channel layer structure suspended above the growth layer; and forming a gate structure, crossing the channel layer structure, over the substrate, where the gate structure is around the one or more channel layers along an extension direction of the gate structure.

In the fabrication method provided by embodiments of the present disclosure, the growth layer for growing the channel material may be formed on the isolation layer; and the stacked-layer structure may be grown on the growth layer, which may realize the process operation of pre-forming the isolation layer before forming the stacked-layer structure. Compared to the solution that the pre-buried layer is first formed at the location for the isolation layer to be formed and the pre-buried layer is removed to form the isolation layer after the stacked-layer structure is formed, in the solution provided by the present disclosure, the operations of removing the pre-buried layer and filling the location of the pre-buried layer to form the isolation layer may be omitted, which may simplify process flow, improve process efficiency, avoid damage to the stacked-layer structure during removal of the pre-buried layer, and also avoid the difficulty in desirably forming the isolation layer due to relatively high process difficulty at the position for filling the pre-buried layer, thereby being beneficial for forming the isolation layer with relatively high-quality film layer, reducing restriction on the film-layer thickness of the isolation layer, and ensuring the isolation performance of the isolation layer. In such way, the channel layer structure may be effectively isolated from the substrate by the isolation layer, thereby being beneficial for reducing the probability of leakage current between the channel layer structure and the substrate and further improving the performance of the semiconductor structure.

To clearly illustrate above-mentioned described objectives, features, and advantages of the present disclosure, various embodiments of the present disclosure are described in detail with reference to accompanying drawings hereinafter.

FIG. 4 illustrates a structural schematic of an exemplary semiconductor structure according to various disclosed embodiments of the present disclosure.

Referring to FIG. 4, the semiconductor structure may include a substrate 100; an isolation layer 110 on the substrate 100; a growth layer 310 on the isolation layer 110, where the growth layer 310 may be configured to grow a channel material; a channel layer structure 240 suspended above the growth layer 310, where the channel layer structure 240 may include one or more channel layers 230 which are spaced apart along the vertical direction; a gate structure 600 over the substrate 100 and crossing the channel layer structure 240, where the gate structure 600 may be around the channel layer 230 along the extension direction of the gate structure 600; and a source-drain doped layer 500, including a source doped layer and a drain doped layer, over the substrate 100 at two opposite sides of the gate structure 600, where the source-drain doped layer 500 (e.g., the source doped layer and the drain doped layer) may be in contact with the ends of the channel layer structure 240 along the extension direction of the channel layer structure 240.

The substrate 100 may provide the process operation basis for the fabrication process of the semiconductor structure. The semiconductor structures may include gate-all-around (GAA) transistors and fork-sheet transistors.

In some embodiments, the substrate 100 may be made of silicon. In other embodiments, the substrate may also be made of other materials including germanium, silicon germanium, silicon carbide, gallium arsenide, indium gallium and/or the like. The substrate may also be made of other types of substrates including a silicon-on-insulator substrate, a germanium-on-insulator substrate and/or the like. The material of the substrate may be a material suitable for process needs or easy to integrate.

The isolation layer 110 may be configured to isolate the channel layer structure 240 from the substrate 100, thereby reducing the probability of leakage between the channel layer structure 240 and the substrate 100.

In one embodiment, the isolation layer 110 may be a bottom dielectric isolation (BDI) structure of the semiconductor structure.

In one embodiment, the material of the isolation layer 110 may include one or more of silicon oxide and silicon nitride.

Using one or more of silicon oxide and silicon nitride may form the isolation layer 110 with desirable isolation performance.

In one embodiment, the isolation layer 110 may cover the substrate 100.

The isolation layer 110 may cover the substrate 100, such that the device formed on the substrate 100 may be desirably and completely isolated from the substrate 100.

The growth layer 310 may be configured to grow the channel material. For example, in one embodiment, the growth layer 310 may be configured to grow the sacrificial layers and the channel layers 230 which are alternatingly stacked with each other. The sacrificial layers may be removed, and one or more channel layers 230 may be retained as the channel layer structure 240.

In one embodiment, the growth layer 310 for growing the channel material may be formed on the isolation layer 110. Therefore, during the fabrication (formation) process, the isolation layer 110 may be first formed; and after the growth layer 310 is formed on the isolation layer 110, the channel layer structure 240 may be grown on the growth layer 310, which may realize the process operation of pre-forming the isolation layer 110 before forming the channel layer structure 240. Compared to the solution that the pre-buried layer is first formed at the location for the isolation layer to be formed and the pre-buried layer is removed to form the isolation layer after the channel layer structure is formed, in the solution provided by the present disclosure, the operations of removing the pre-buried layer and filling the location of the pre-buried layer to form the isolation layer 110 may be omitted, which may simplify process flow, improve process efficiency, avoid damage to the channel layer structure 240 during removal of the pre-buried layer, and also avoid the difficulty in desirably forming the isolation layer 110 due to relatively high process difficulty at the position for filling the pre-buried layer, thereby being beneficial for forming the isolation layer 110 with relatively high-quality film layer, reducing restriction on the film-layer thickness of the isolation layer 110, and ensuring the isolation performance of the isolation layer 110. In such way, the channel layer structure 240 may be effectively isolated from the substrate 100 by the isolation layer 110, thereby being beneficial for reducing the probability of leakage current between the channel layer structure 240 and the substrate 100 and further improving the performance of the semiconductor structure.

In one embodiment, the channel layer structure 240 and the growth layer 310 may be patterned together during the semiconductor structure fabrication process. Therefore, in one embodiment, the sidewalls of the growth layer 310 may be coplanar with the ends of the channel layer structure 240.

In one embodiment, the material of the growth layer 310 may include silicon; and the material of the growth layer 310 may be single crystalline silicon or epitaxial-like crystalline silicon.

The material of the growth layer 310 may include silicon; and the material of the growth layer 310 may be single crystalline (single crystal) silicon or epitaxial-like crystalline silicon. In such way, the single crystalline material may be epitaxially grown on the growth layer 310. For example, the single crystalline silicon epitaxially grown may be configured as the channel layer 230.

Accordingly, in one embodiment, the growth layer 310 may be made of a semiconductor channel material, such that the growth layer 310 and the channel layer 230 may be together configured as the channel(s) of the transistor.

The channel layer structure 240 may be configured as the channel of the transistor. For example, the top, the bottom, and the sidewall of the channel layer 230 may all be configured as the channel.

In one embodiment, the channel layer 230 may be made of a material including silicon, germanium, silicon germanium, a Group III-V semiconductor material, or a combination thereof. In one embodiment, the material of the channel layer 230 may be silicon. In other embodiments, the material of the channel layer may be determined by the type and performance of the transistor.

The gate structure 600 may be configured to control the turn-on and turn-off state of the transistor channel.

The gate structure 600 may be around and cover the channel layer 230. Therefore, the top, the bottom, and the sidewall of the channel layer 230 may all function as the channel, which may increase the area of the channel layer 230 available for the channel, thereby increasing the operating current of the semiconductor structure.

In one embodiment, the gate structure 600 may include a gate dielectric layer around and covering the channel layer 230, and a gate electrode layer covering the gate dielectric layer.

The gate dielectric layer may be configured to isolate the gate electrode layer from both the channel layer 230 and the growth layer 310.

The gate dielectric layer may be made of a material including HfO₂, ZrO₂, HfSiO, HfSiON, HfTaO, HfTiO, HfZrO, Al₂O₃, SiO₂, La₂O₃, and/or a combination thereof. In one embodiment, the gate dielectric layer may include a high-k gate dielectric layer; and the material of the high-k gate dielectric layer may include a high-k dielectric material. The high-k dielectric material refers to a dielectric material having a relative dielectric constant greater than the relative dielectric constant of silicon oxide. For example, the high-k gate dielectric layer may be made of a material including HfO₂, ZrO₂, HfSiO, HfSiON, HfTaO, HfTiO, HfZrO, Al₂O₃, and/or a combination thereof.

It should be noted that the gate dielectric layer may also include a gate oxide layer; and the gate oxide layer may be between the high-k gate dielectric layer and the channel 230. For example, the gate oxide layer may be made of silicon oxide.

In some embodiments, the gate structure 600 may be a metal gate structure. Therefore, the gate electrode layer may be made of a material including TiN, TaN, Ta, Ti, TiAl, W, Al, TiSiN, TiAlC, and/or a combination thereof.

For example, the gate electrode layer may include a work function layer (not shown), and an electrode layer (not shown) on the work function layer. The work function layer may be configured to adjust the threshold voltage of the transistor, and the electrode layer may be configured to lead out the electrical properties of the metal gate structure.

In other embodiments, the gate electrode layer may include only the work function layer.

In other embodiments, according to process requirements, the gate structure may also be a polysilicon gate structure.

The source-drain doped layer 500 may be configured as the source region or the drain region of the transistor. For example, the doping type of the source-drain doped layer 500 may be same as the channel conductivity type of corresponding transistor.

In one embodiment, the source-drain doped layer 500 may be on the isolation layer 110 which is on the substrate 100.

The source-drain doped layer 500 may be on the isolation layer 110 which is on the substrate 100, such that the source-drain doped layer 500 may be isolated from the substrate 100 via the isolation layer 110, thereby being beneficial for reducing the probability of leakage current between the source-drain doped layer 500 and the substrate 100.

In one embodiment, the growth layer 310 may be coplanar with the sidewall of the channel layer 230; and the growth layer 310 and the channel layer 230 may be together configured as the channel of the transistor. Accordingly, in one embodiment, the source-drain doped layer 500 may be also in contact with the sidewall of the growth layer 310 along the extension direction of the channel layer structure 240.

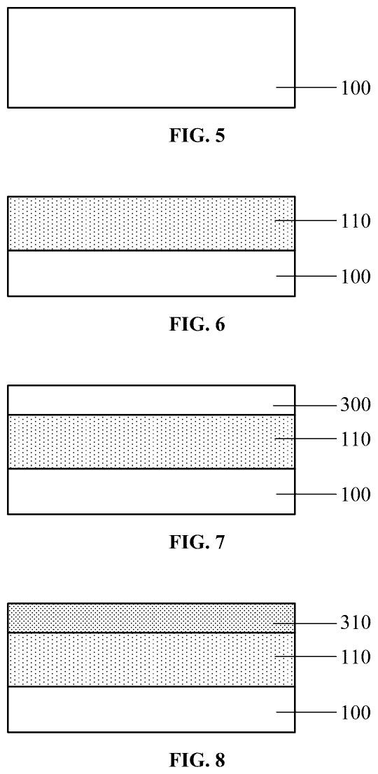

FIGS. 5-12 illustrate structural schematics corresponding to certain stages of an exemplary fabrication method of a semiconductor structure according to various disclosed embodiments of the present disclosure.

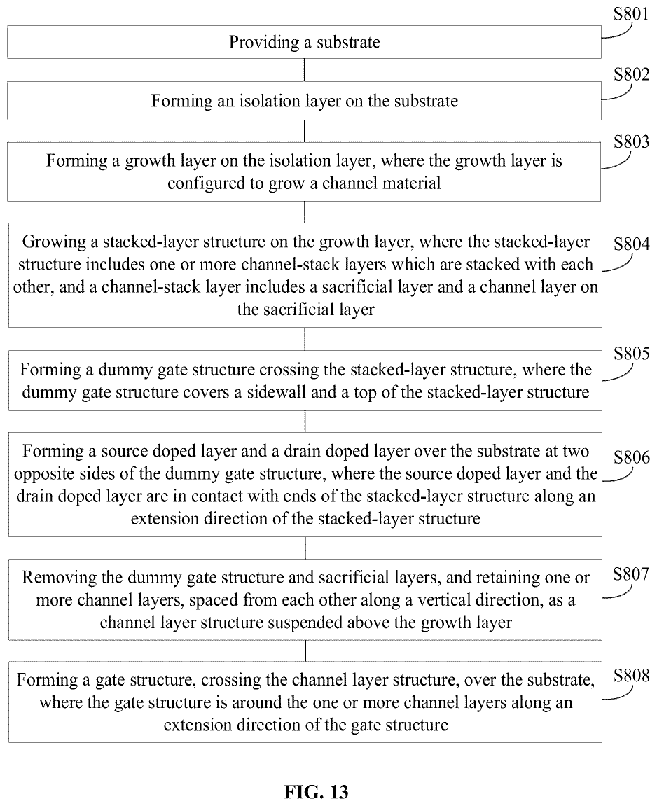

Referring to FIG. 5, the substrate 100 may be provided (e.g., in S801 of FIG. 13).

The substrate 100 may provide the process operation basis for the fabrication process of the semiconductor structure. The semiconductor structures may include gate-all-around (GAA) transistors and fork-sheet transistors.

In some embodiments, the substrate 100 may be made of silicon. In other embodiments, the substrate may also be made of other materials including germanium, silicon germanium, silicon carbide, gallium arsenide, indium gallium and/or the like. The substrate may also be made of other types of substrates including a silicon-on-insulator substrate, a germanium-on-insulator substrate and/or the like. The material of the substrate may be a material suitable for process needs or easy to integrate.

Referring to FIG. 6, the isolation layer 110 may be formed on substrate 100 (e.g., in S802 of FIG. 13).

The isolation layer 110 may be configured to isolate the channel layer structure 240 from the substrate 100, thereby reducing the probability of leakage between the channel layer structure 240 and the substrate 100.

In one embodiment, the isolation layer 110 may be a bottom dielectric isolation (BDI) structure of the semiconductor structure.

In one embodiment, during the operation of forming the isolation layer 110 on the substrate 100, the isolation layer 110 may cover the substrate 100.

The isolation layer 110 may cover the substrate 100, such that the device formed on the substrate 100 may be desirably and completely isolated from the substrate 100.

In one embodiment, during the operation of forming the isolation layer 110 on the substrate 100, the material of the isolation layer 110 may include one or more of silicon oxide and silicon nitride.

Using one or more of silicon oxide and silicon nitride may form the isolation layer 110 with desirable isolation performance.

In one embodiment, the operation of forming the isolation layer 110 on the substrate 100 may include converting a top portion of the substrate 100 into the isolation layer 110 and retaining remaining portion of the substrate 100.

The top portion of the substrate 100 may be converted into the isolation layer 110. That is the isolation layer 110 may be self-formed at the top of the substrate 100. The thickness of the isolation layer 110 may be flexibly adjusted, which may reduce the thickness restriction on the isolation layer 110 and be beneficial for forming the isolation layer 110 with relatively large thickness, such that the isolation layer 110 may achieve desirable isolation effect.

In one embodiment, the top portion of the substrate 100 may be oxidized, such that the top portion of the substrate 100 may be converted into the isolation layer 110.

The top portion of the substrate 100 may be oxidized, such that the top portion of the substrate 100 may be converted into the isolation layer 110. The oxidation process may be simple and easy to operate. The oxidation process manner may be used to oxidize the portion of silicon into silicon oxide which may be configured as the isolation layer 110 with desirable isolation effect.

For example, in one embodiment, the operation of oxidizing the top portion of the substrate 100 may include performing an oxidization process on the top portion of the substrate 100 using an in-situ steam oxidation process; or performing an oxygen ion implantation process on the top portion of the substrate 100 and performing an annealing process on the top portion of the substrate 100 after performing oxygen ion implantation process.

In other embodiments, the operation of forming the isolation layer on the substrate may further include forming the isolation layer on the substrate to cover the substrate.

The isolation layer covering the substrate may be directly formed to cover the substrate, which may be beneficial for flexible selection of isolation layer materials.

For example, in other embodiments, a deposition process may be configured to form the isolation layer covering the substrate.

Referring to FIGS. 7-8, the growth layer 310 may be formed on the isolation layer 110; and the growth layer 310 may be configured to grow the channel material (e.g., in S803 of FIG. 13).

The growth layer 310 may be configured to grow the channel material. For example, in one embodiment, the growth layer 310 may be configured to grow the sacrificial layers and the channel layers which are alternating stacked with each other to form the stacked-layer structure.

In one embodiment, after forming the growth layer 310 on the isolation layer 110, the stacked-layer structure may be grown on the growth layer 310, which may realize the process operation of pre-forming the isolation layer 110 before forming the stacked-layer structure. Compared to the solution that the pre-buried layer is first formed at the location for the isolation layer to be formed and the pre-buried layer is removed to form the isolation layer after the channel layer structure is formed, the operations of removing the pre-buried layer and filling the location of the pre-buried layer to form the isolation layer 110 may be omitted, which may simplify process flow, improve process efficiency, avoid damage to the stacked-layer structure during removal of the pre-buried layer, and also avoid the difficulty in forming the isolation layer 110 due to the difficulty in filling the pre-buried layer, thereby being beneficial for forming the isolation layer 110 with relatively high-quality film quality, reducing restriction on the thickness of the isolation layer 110, and ensuring the isolation performance of the isolation layer 110. In such way, the channel layer structure may be effectively isolated from the substrate 100 by the isolation layer 110, thereby being beneficial for reducing the probability of leakage current between the channel layer structure and the substrate 100 and further improving the performance of the semiconductor structure.

In one embodiment, during the operation of forming the growth layer 310 on the isolation layer 110, the material of the growth layer 310 may include silicon, and the material of the growth layer 310 may be single crystalline (single crystal) silicon or epitaxial-like crystalline silicon.

The material of the growth layer 310 may include silicon; and the material of the growth layer 310 may be single crystalline (single crystal) silicon or epitaxial-like crystalline silicon. In such way, the single crystalline material may be epitaxially grown on the growth layer 310. For example, the single crystalline silicon epitaxially grown may be configured as the channel layer.

Accordingly, in one embodiment, the growth layer 310 may be made of a semiconductor channel material, such that the growth layer 310 and the channel layer 230 may be together configured as the channel(s) of the transistor.

Referring to FIG. 7, the operation of forming the growth layer 310 on the isolation layer 110 may include forming an initial growth layer 300 covering the isolation layer 110.

The initial growth layer 300 may be configured to be modified into the growth layer 310. Accordingly, the initial growth layer 300 may be formed of same material as the growth layer 310, and the lattice structure of the initial growth layer 300 may have not been processed.

In one embodiment, during the operation of forming the initial growth layer 300 covering the isolation layer 110, the material of the initial growth layer 300 may include polycrystalline silicon.

Polycrystalline silicon may be used to form the initial growth layer 300, such that the growth layer 310 formed may be also made of silicon; and the polycrystalline silicon may be lattice-reorganized to form single crystalline silicon or epitaxial-like crystalline silicon capable of growing the channel material.

In one embodiment, a deposition process may be configured to form the initial growth layer 300 covering the isolation layer 110.

Referring to FIG. 8, the initial growth layer 300 may be lattice-reorganized to form the growth layer 310.

The initial growth layer 300 may be lattice-reorganized to form the growth layer 310 capable of growing the channel material.

In one embodiment, during the operation of lattice-reorganizing the initial growth layer 300 to form the growth layer 310, the material of the growth layer 310 may include single crystalline silicon or epitaxial-like crystalline silicon.

The initial growth layer 300 may be made of polycrystalline silicon. The initial growth layer 300 may be lattice-reorganized, such that the grain size of the polycrystalline silicon may increase to form a lattice structure, which is like or converted into crystalline silicon, thereby forming the growth layer 310 of single crystalline silicon or epitaxial-like silicon.

It should be noted that the channel layer configured as the channel may need a single crystalline lattice structure. Therefore, the growth layer 310 of single crystalline silicon or epitaxial-like silicon may be formed, such that single crystalline silicon may be epitaxially grown on the growth layer 310 as the channel layer.

For example, in one embodiment, the initial growth layer 300 may be lattice-reorganized, by a laser processing, to form the growth layer 310.

The initial growth layer 300 may be lattice-reorganized by a laser processing, such that the grain size of the polycrystalline silicon may increase and the grain boundary change may be relatively small to form a lattice structure, which is like or converted into crystalline silicon, thereby forming the growth layer 310 of single crystalline silicon or epitaxial-like silicon.

For example, the initial growth layer 300 may be lattice-reorganized, by an excimer laser annealing, to form the growth layer 310.

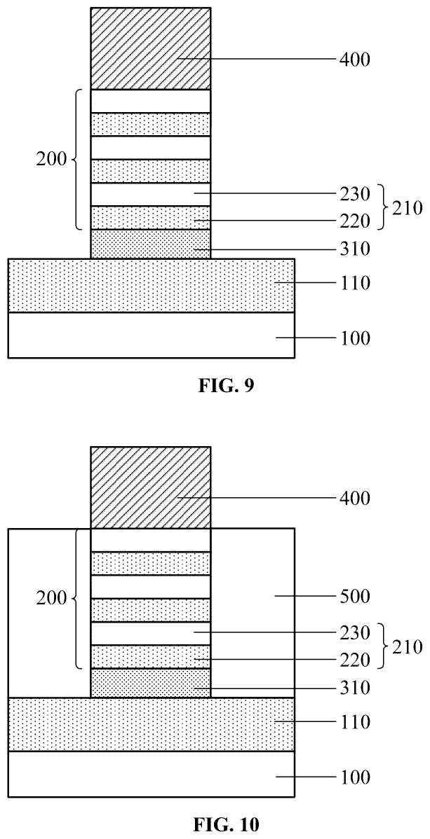

Referring to FIG. 9, the stacked-layer structure 200 may be grown on the growth layer 310; the stacked-layer structure 200 may include one or more channel-stack layers 210 which are stacked with each other; and the channel stack 210 may include the sacrificial layer 220 and the channel layer 230 on the sacrificial layer 220 (e.g., in S804 of FIG. 13).

The channel layer 230 in the stacked-layer structure 200 may be configured as the channel of the semiconductor structure. The sacrificial layer 220 may be configured to provide the process basis for subsequent suspended configuration of the channel layer 230 and occupy space for subsequently formed gate structure. In subsequent fabrication process, the sacrificial layer 220 may be removed, such that the channel layer 230 may be suspended. The gate structure may be formed between the channel layer 230 and the substrate 100, and between adjacent channel layers 230.

The surface of the channel layer 230 covered by the gate structure may be configured as the channel. In one embodiment, the top, the bottom, and the sidewall of the channel layer 230 may all function as the channel, which may increase the area of the channel layer 230 available for the channel, thereby increasing the operating current of the semiconductor structure.

In one embodiment, the channel layer 230 may be made of a material including silicon, germanium, silicon germanium, a Group III-V semiconductor material, or a combination thereof. In one embodiment, the material of the channel layer 230 may be silicon. In other embodiments, the material of the channel layer may be determined by the type and performance of the transistor.

It should be noted that the growth layer 310 may be single crystalline silicon or epitaxial-like crystalline silicon. Therefore, single crystalline silicon may be epitaxially grown on the growth layer 310 configured as the channel layer 230.

In one embodiment, the material of the sacrificial layer 220 may include silicon germanium.

Silicon germanium may have a relatively large etching selectivity with silicon, which may be beneficial for subsequent removal of the sacrificial layer 220 and reducing damage to the channel layer 230.

In other embodiments, according to the channel layer material, the sacrificial layer may be made of a material that has an appropriate etching selectivity with the channel layer, such that the damage to the channel layer may be minimized during subsequent removal of the sacrificial layer.

Accordingly, in one embodiment, an epitaxial growth process may be configured to grow the stacked-layer structure 200 on the growth layer 310.

The epitaxial growth process may have desirable control of process parameters and relatively high process controllability, such that relatively precise film layer thickness may be obtained. Furthermore, the epitaxial growth process may facilitate the formation of the film layer with less impurities, which may result in the channel layer 230 and the sacrificial layer 220 with relatively high quality.

Referring again to FIG. 9, a dummy gate structure 400 crossing the stacked-layer structure 200 may be formed; and the dummy gate structure 400 may cover the sidewall and the top of the stacked-layer structure 200 (e.g., in S805 of FIG. 13).

The dummy gate structure 400 may be configured to occupy space for subsequent formation of the gate structure.

For example, the dummy gate structure 400 may be a stacked-layer structure including a dummy gate oxide layer (not shown) and a dummy gate layer (not shown) covering the dummy gate oxide layer.

As an example, the dummy gate oxide layer may be made of silicon oxide, and the dummy gate layer may be made of polysilicon.

In one embodiment, after forming the dummy gate structure 400 crossing the stacked-layer structure 200, the method may further include patterning the stacked-layer structure 200 and the growth layer 310 at two sides of the dummy gate structure 400 along the sidewalls of the dummy gate structure 400, which may prepare for subsequent formation of the source-drain doped layer.

Accordingly, in one embodiment, the sidewall of the growth layer 310 may be coplanar with the end of the stacked-layer structure 200.

Referring to FIG. 10, the source-drain doped layer 500 may be formed on the substrate 100 at two sides of the dummy gate structure 400; and along the extension direction of the stacked-layer structure 200, the source-drain doped layer 500 may be in contact with the end of the stacked-layer structure 200 (e.g., in S806 of FIG. 13).

The source-drain doped layer 500 may be configured as the source region or the drain region of the transistor. For example, the doping type of the source-drain doped layer 500 may be same as the channel conductivity type of corresponding transistor.

In one embodiment, during the operation of forming the source-drain doped layer 500 on the substrate 100 at two sides of the dummy gate structure 400, the source-drain doped layer 500 may be on the isolation layer 110 which is on the substrate 100.

The source-drain doped layer 500 may be on the isolation layer 110 which is on the substrate 100, such that the source-drain doped layer 500 may be isolated from the substrate 100 via the isolation layer 110, thereby being beneficial for reducing the probability of leakage current between the source-drain doped layer 500 and the substrate 100.

In one embodiment, the growth layer 310 may be coplanar with the sidewall of the channel layer 230; and the growth layer 310 and the channel layer 230 may be together configured as the channel of the transistor. Accordingly, in one embodiment, during the operation of forming the source-drain doped layer 500 on the substrate 100 at two sides of the dummy gate structure 400, the source-drain doped layer 500 may be also in contact with the sidewall of the growth layer 310 along the extension direction of the stacked-layer structure 200.

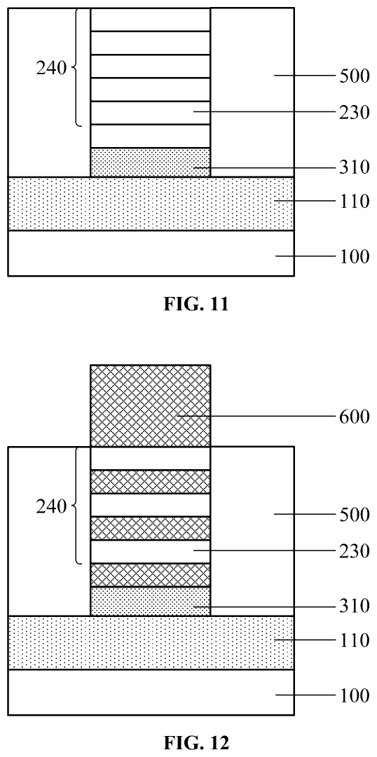

Referring to FIG. 11, the dummy gate structure 400 and the sacrificial layer 220 may be removed; and one or more channel layers 230 which are spaced apart from each other along the vertical direction may be retained as the channel layer structure 240 suspended above the growth layer 310 (e.g., in S807 of FIG. 13).

The dummy gate structure 400 and the sacrificial layer 220 may be removed to prepare for subsequent formation of the gate structure surrounding and covering the channel layer 230.

Referring to FIG. 12, the gate structure 600 crossing the channel layer structure 240 may be formed on the substrate 100; and the gate structure 600 may be around the channel layer 230 along the extension direction of the gate structure 600 (e.g., in S808 of FIG. 13).

The gate structure 600 may be configured to control the turn-on and turn-off state of the transistor channel.

The gate structure 600 may be around and cover the channel layer 230. Therefore, the top, the bottom, and the sidewall of the channel layer 230 may all function as the channel, which may increase the area of the channel layer 230 available for the channel, thereby increasing the operating current of the semiconductor structure.

In one embodiment, the gate structure 600 may include a gate dielectric layer around and covering the channel layer 230, and a gate electrode layer covering the gate dielectric layer.

The gate dielectric layer may be configured to isolate the gate electrode layer from both the channel layer 230 and the growth layer 310.

The gate dielectric layer may be made of a material including HfO₂, ZrO₂, HfSiO, HfSiON, HfTaO, HfTiO, HfZrO, Al₂O₃, SiO₂, La₂O₃, and/or a combination thereof. In one embodiment, the gate dielectric layer may include a high-k gate dielectric layer; and the material of the high-k gate dielectric layer may include a high-k dielectric material. The high-k dielectric material refers to a dielectric material having a relative dielectric constant greater than the relative dielectric constant of silicon oxide. For example, the high-k gate dielectric layer may be made of a material including HfO₂, ZrO₂, HfSiO, HfSiON, HfTaO, HfTiO, HfZrO, Al₂O₃, and/or a combination thereof.

It should be noted that the gate dielectric layer may also include a gate oxide layer; and the gate oxide layer may be between the high-k gate dielectric layer and the channel 230. For example, the gate oxide layer may be made of silicon oxide.

In some embodiments, the gate structure 600 may be a metal gate structure. Therefore, the gate electrode layer may be made of a material including TiN, TaN, Ta, Ti, TiAl, W, Al, TiSiN, TiAlC, and/or a combination thereof.

For example, the gate electrode layer may include a work function layer (not shown), and an electrode layer (not shown) on the work function layer. The work function layer may be configured to adjust the threshold voltage of the transistor, and the electrode layer may be configured to lead out the electrical properties of the metal gate structure.

In other embodiments, the gate electrode layer may include only the work function layer.

In other embodiments, according to process requirements, the gate structure may also be a polysilicon gate structure.

Although the present disclosure has been disclosed above, the present disclosure may be not limited thereto. Any changes and modifications may be made by those skilled in the art without departing from the spirit and scope of the disclosure, and the scope of the disclosure should be determined by the scope defined by the appended claims.

What is claimed is

1. A semiconductor structure, comprising:
a substrate;
an isolation layer, on the substrate;
a growth layer, on the isolation layer and configured to grow a channel material;
a channel layer structure, suspended above the growth layer, wherein the channel layer structure includes one or more channel layers spaced from each other along a vertical direction;
a gate structure, over the substrate and crossing the channel layer structure, wherein the gate structure is around the one or more channel layers along an extension direction of the gate structure; and
a source doped layer and a drain doped layer, over the substrate at two opposite sides of the gate structure, wherein along an extension direction of the channel layer structure, the source doped layer and the drain doped layer are in contact with ends of the channel layer structure.

2. The semiconductor structure according to claim 1, wherein:
the isolation layer covers the substrate; and
the source doped layer and the drain doped layer are on the isolation layer which is on the substrate.

3. The semiconductor structure according to claim 1, wherein:
a sidewall of the growth layer is coplanar with the end of the channel layer structure; and
along the extension direction of the channel layer structure, the source doped layer and the drain doped layer are also in contact with sidewalls of the growth layer.

4. The semiconductor structure according to claim 1, wherein:
the substrate material is made of a material including silicon.

5. The semiconductor structure according to claim 1, wherein:
the isolation layer is made of a material including silicon oxide, silicon nitride, or a combination thereof.

6. The semiconductor structure according to claim 1, wherein:
the growth layer is made of a material including silicon which includes single crystalline silicon or epitaxial-like crystalline silicon.

7. The semiconductor structure according to claim 1, wherein:
the channel layer is made of a material including silicon, germanium, silicon germanium, a Group III-V semiconductor material, or a combination thereof.

8. A fabrication method of a semiconductor structure, comprising:
providing a substrate;
forming an isolation layer on the substrate;
forming a growth layer on the isolation layer, wherein the growth layer is configured to grow a channel material;
growing a stacked-layer structure on the growth layer, wherein the stacked-layer structure includes one or more channel-stack layers which are stacked with each other, and a channel-stack layer includes a sacrificial layer and a channel layer on the sacrificial layer;
forming a dummy gate structure crossing the stacked-layer structure, wherein the dummy gate structure covers a sidewall and a top of the stacked-layer structure;
forming a source doped layer and a drain doped layer over the substrate at two opposite sides of the dummy gate structure, wherein the source doped layer and the drain doped layer are in contact with ends of the stacked-layer structure along an extension direction of the stacked-layer structure;
removing the dummy gate structure and sacrificial layers, and retaining one or more channel layers, spaced from each other along a vertical direction, as a channel layer structure suspended above the growth layer; and
forming a gate structure, crossing the channel layer structure, over the substrate, wherein the gate structure is around the one or more channel layers along an extension direction of the gate structure.

9. The fabrication method according to claim 8, wherein forming the isolation layer on the substrate includes:
forming the isolation layer, which covers the substrate, on the substrate.

10. The fabrication method according to claim 9, wherein:
the isolation layer which covers the substrate is formed using a deposition process.

11. The fabrication method according to claim 8, wherein forming the isolation layer on the substrate includes:
converting a top portion of the substrate into the isolation layer and retaining a remaining portion of the substrate.

12. The fabrication method according to claim 11, wherein:
an oxidation processing is performed on the top portion of the substrate to convert the top portion of the substrate into the isolation layer.

13. The fabrication method according to claim 12, wherein performing the oxidation processing on the top portion of the substrate to convert the top portion of the substrate into the isolation layer includes:
performing the oxidation processing on the top portion of the substrate using an in-situ water vapor oxidation process; or
performing an oxygen ion implantation processing on the top portion of the substrate; and after performing the oxygen ion implantation processing, performing an annealing processing on the top portion of the substrate.

14. The fabrication method according to claim 8, wherein forming the growth layer on the isolation layer includes:
forming an initial growth layer covering the isolation layer; and
performing lattice reorganization on the initial growth layer to form the growth layer.

15. The fabrication method according to claim 14, wherein:
for forming the initial growth layer covering the isolation layer, the initial growth layer is made of a material including polycrystalline silicon; and
for performing the lattice reorganization on the initial growth layer to form the growth layer, the growth layer is made of a material including single crystalline silicon and/or epitaxial-like crystalline silicon.

16. The fabrication method according to claim 14, wherein:
the initial growth layer covering the isolation layer is formed using a deposition process.

17. The fabrication method according to claim 14, wherein:
a laser processing is configured to perform the lattice reorganization on the initial growth layer to form the growth layer.

18. The fabrication method according to claim 8, wherein:
the stacked-layer structure is grown on the growth layer using an epitaxial growth process.

19. The fabrication method according to claim 8, wherein forming the source doped layer and the drain doped layer over the substrate at two opposite sides of the dummy gate structure includes:
forming the source doped layer and the drain doped layer on the isolation layer which is on the substrate at two opposite sides of the dummy gate structure.

20. The fabrication method according to claim 8, wherein:
for forming the source doped layer and the drain doped layer over the substrate at two opposite sides of the dummy gate structure, the source doped layer and the drain doped layer are further in contact with sidewalls of the growth layer along the extension direction of the stacked-layer structure.
